(19) United States
(12) Patent Application Publication
(10) Pub. No.: US 2023/0187236 A1
(43) Pub. Date: Jun. 15, 2023

(54) WAFER BAKING APPARATUS

(71) Applicant: SAMSUNG ELECTRONICS CO., LTD., Suwon-si (KR)

(72) Inventors: Wonguk Seo, Gunpo-si (KR); Seok Heo, Hwaseong-si (KR); Sungwook Kang, Seoul (KR); Byeongsang Kim, Hwaseong-si (KR); Sungkun Hwang, Suwon-si (KR); Igor Ivanov, Suwon-si (KR)

(73) Assignee: SAMSUNG ELECTRONICS CO., LTD., Suwon-si (KR)

(21) Appl. No.: 17/889,035

(22) Filed: Aug. 16, 2022

(30) Foreign Application Priority Data
Dec. 9, 2021 (KR) 10-2021-0175462

(51) Int. Cl. H01L 21/67; H01L 21/687; H05B 3/26; F27B 17/00; F27D 5/00; B32B 9/00; B32B 9/04; B32B 18/00; B32B 7/12; B32B 3/30; B32B 3/14

(52) U.S. Cl. CPC H01L 21/67109; B32B 3/14; B32B 3/30; B32B 7/12; B32B 9/04; B32B 9/007; B32B 9/041; B32B 18/00; F27B 17/0025; F27D 5/0037; H01L 21/6875; H05B 3/265; B32B 2255/205; B32B 2307/302; H05B 2203/005; H05B 2214/04

(57) ABSTRACT

A wafer baking apparatus includes a chamber including a processing space, and a wafer heater disposed in the processing space and configured to support a wafer. The wafer heater includes a first heating plate, a heating resistance pattern disposed on a lower surface of the first heating plate, a second heating plate disposed on the first heating plate, and a heat dispersion layer interposed between the first and second heating plates and having thermal conductivity lower than a thermal conductivity of materials of the first and second heating plates.

### CROSS-REFERENCE TO RELATED APPLICATION

This application claims the benefit under 35 USC 119(a) of Korean Patent Application No. 10-2021-0175462 filed on Dec. 9, 2021 in the Korean Intellectual Property Office, the entire disclosure of which is incorporated herein by reference for all purposes.

### BACKGROUND

Embodiments of the present disclosure relate to a wafer baking apparatus.

Semiconductor device manufacturing processes may include various unit processes such as a photolithography process, thin film deposition, and ion implantation. In detail, the photolithography process is a process for forming a pattern on a semiconductor and corresponds to a relatively important process for high integration.

The photolithography process may include coating and exposing a photoresist layer for forming a pattern on a semiconductor wafer, and then performing a baking process for removing solvent from a photoresist layer. Such a baking process may be performed by a baking apparatus having a heater.

Since the thickness of the photoresist layer may vary locally depending on the degree of evaporation of the solvent, uniform temperature control over the entire area of the wafer during baking may be relatively important.

### SUMMARY

Example embodiments provide a wafer baking apparatus having a heating plate capable of controlling a wafer to have a uniform temperature at a relatively high level over the entire area of the wafer.

According to embodiments of the present disclosure, a wafer baking apparatus is provided. The wafer baking apparatus includes: a chamber including a processing space; and a wafer heater disposed in the processing space and configured to support a wafer; wherein the wafer heater includes: a first heating plate; a heating resistance pattern disposed on a lower surface of the first heating plate; a second heating plate disposed on the first heating plate; and a heat dispersion layer interposed between the first heating plate and the second heating plate, and having a thermal conductivity that is lower than a thermal conductivity of materials of the first heating plate and the second heating plate.

According to embodiments of the present disclosure, a wafer baking apparatus is provided. The wafer baking apparatus includes: a chamber including a processing space; and a wafer heater disposed in the processing space, configured to support a wafer, and defining a plurality of heating sectors in a plan view, wherein the wafer heater includes: a first heating plate including a plurality of receiving grooves respectively disposed in upper surface regions of the first heating plate that correspond to the plurality of heating sectors; a plurality of heating resistance patterns disposed in the plurality of heating sectors, respectively, and configured to be controlled to heat independently from each other; a plurality of second heating plates disposed in the plurality of receiving grooves, respectively; and a plurality of heat dispersion layers that each have a thermal conductivity that is lower than a thermal conductivity of materials of the first heating plate and the plurality of second heating plates, the plurality of heat dispersion layers being between bottom surfaces of the plurality of receiving grooves and a top surface of the plurality of second heating plates.

According to embodiments of the present disclosure, a wafer baking apparatus is provided. The wafer baking apparatus includes: a chamber including a processing space; and a wafer heater disposed in the processing space and configured to support a wafer, wherein the wafer heater includes: a heating plate; a heating resistance pattern disposed on a lower surface of the heating plate; and a heat dispersion layer disposed on the heating plate and having a horizontal thermal conductivity that is greater than a vertical thermal conductivity of the heat dispersion layer.

### BRIEF DESCRIPTION OF DRAWINGS

The above and other aspects, features, and advantages of embodiments of the present disclosure will be more clearly understood from the following detailed description, taken in conjunction with the accompanying drawings, in which:

FIG. 1 is a schematic cross-sectional view illustrating a wafer baking apparatus according to an example embodiment;

FIG. 2 is a bottom view illustrating a wafer heater employed in the wafer baking apparatus of FIG. 1;

FIG. 3 is a diagram that includes a cross-sectional view of a wafer heater and a temperature distribution of a wafer introduced into the wafer baking apparatus of FIG. 1;

FIG. 4 is a graph illustrating heat transfer characteristics in a vertical direction (thickness direction of a heating plate) according to the introduction of an air gap;

FIG. 5A is a graph illustrating a temperature distribution of a wafer that does not include a heat dispersion layer according to a comparative embodiment;

FIG. 5B is a graph illustrating a temperature distribution of a wafer that does include an air gap according to an example embodiment;

FIG. 6A is a graph illustrating a temperature distribution of a wafer that does not include a heat dispersion layer according to a comparative embodiment;

FIG. 6B is a graph illustrating a temperature distribution of a wafer that does include an air gap according to an example embodiment;

FIG. 7 is a cross-sectional view illustrating a wafer heater according to an example embodiment;

FIG. 8 is a cross-sectional view illustrating a wafer heater according to an example embodiment;

FIG. 9 is a partially enlarged view illustrating portion “A” of the wafer heater of FIG. 8;

FIG. 10 is a top plan view illustrating the wafer heater of FIG. 8;

FIG. 11 is a cross-sectional view illustrating a wafer heater according to an example embodiment;

FIG. 12 is a top plan view illustrating the wafer heater of FIG. 11;

FIG. 13A is a cross-sectional view illustrating a wafer heater according to an example embodiment;

FIG. 13B is a cross-sectional view illustrating a wafer heater according to an example embodiment; and

FIG. 13C is a cross-sectional view illustrating a wafer heater according to an example embodiment.

### DETAILED DESCRIPTION

Hereinafter, various embodiments will be described in detail with reference to the accompanying drawings.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

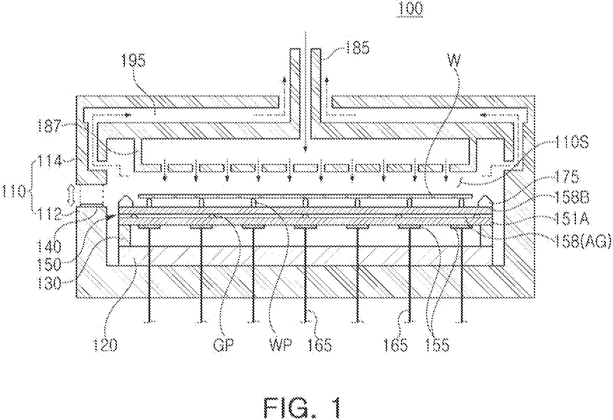

FIG. 1 is a schematic cross-sectional view illustrating a wafer baking apparatus according to an example embodiment.

Referring to FIG. 1, a wafer baking apparatus 100 according to an example embodiment includes a chamber 110 having an inner space 110S for processing a wafer W, and a wafer heater 150 disposed in the inner space 110S and supporting the wafer W.

The chamber 110 includes a base 112 and a cover 114 disposed on the base 112. A connection opening through which the wafer W is loaded/unloaded to/from the inner space 110S of the chamber 110 is provided in one side of the chamber 110, and a shutter 140 for opening and closing the connection opening may be mounted. For example, the shutter 140 may be configured to operate up/down (see arrows) to open/close the connection opening.

As described above, the wafer heater 150 that is configured to heat the wafer W while supporting the wafer W is disposed in the inner space 110S of the chamber 110.

The wafer heater 150 employed in this embodiment may include a first heating plate 151A, a second heating plate 151B disposed on the first heating plate 151A, and a heat dispersion layer 158 interposed between the first heating plate 151A and the second heating plate 151B. In addition, a plurality of a heating resistance pattern 155 (i.e., heater element) may be attached to a lower surface of the first heating plate 151A. Each of the plurality of the heating resistance pattern 155 may act as a heating source for the wafer heater 150 by a voltage applied by being connected to the power line 165.

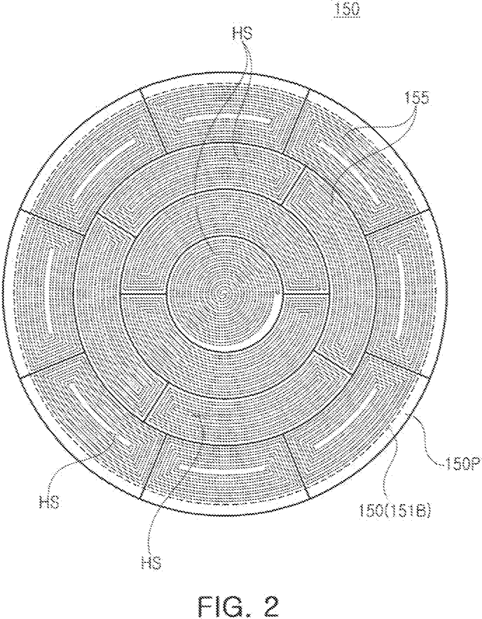

As illustrated in FIG. 2, the wafer heater 150 employed in this embodiment may be divided into a plurality of heating sectors HS in a plan view. The heating resistance pattern 155 may be disposed in each of the plurality of heating sectors HS to independently control the temperature of each of the plurality of heating sectors HS. In the present embodiment, a form divided into 15 heating sectors HS is provided as an example, but the number of heating sectors HS is not limited thereto.

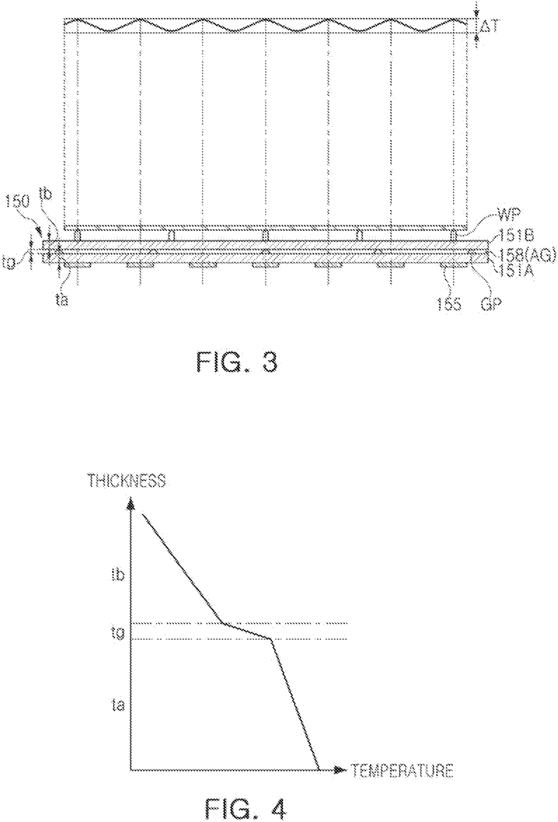

The heating resistance pattern 155 may be formed of heating wire patterns arranged for uniform heating. As illustrated in FIG. 2, the plurality of the heating resistance pattern 155 may be arranged in a zig-zag pattern on the lower surface of the first heating plate 151A along the outer periphery to have a plurality of arcuate shapes. The arrangement of the heating resistance pattern 155 is not limited thereto, and may have various other arrangements (width and spacing) for uniform temperature distribution. In the related art, although it was attempted to implement a uniform temperature distribution with a width and spacing of a heating resistance pattern, there has been a limitation in implementing a temperature distribution of a required level due to process deviations. This embodiment provides a method of implementing a uniform temperature distribution by interposing the heat dispersion layer 158 as a heat resistance element between the first heating plate 151A and the second heating plate 151B, and a detailed description thereof will be described later with reference to FIGS. 3 to 6.

The heating resistance pattern 155 may be divided into a metal heating element and a non-metal heating element. For example, the metal heating element includes nickel alloy, inconel, kanthal, nikrothal, and the like, and the non-metal heating element may include silicon carbide or pyromax. The heating resistance pattern 155 may be formed in various manners. In an example, the heating resistance pattern 155 may be formed through an etching process or etching after forming a heating resistance layer on the lower surface of the first heating plate 151A. In another example, the heating resistance pattern 155 may be formed by attaching or directly printing an insulating film (e.g., polyimide) on the lower surface of the first heating plate 151A after being prepared in advance as a heating wire pattern.

The heat dispersion layer 158 is a heat resistance element disposed between the first heating plate 151A and the second heating plate 151B, and may be formed of a material having a thermal conductivity that is lower than a thermal conductivity of materials of the first heating plate 151A and the second heating plate 151B.

Referring to FIGS. 1 and 3, the heat dispersion layer 158 may be an air gap AG filled with air, as an empty space. When the air gap AG employed in this embodiment has a thin thickness tg (e.g., 100 µm or less), the air gap may exhibit a conduction characteristic rather than a convection characteristic in terms of heat transfer, and may be used as an excellent thermal resistance element with relatively low thermal conductivity (e.g., about 0.024 W/mk).

The first heating plate 151A may have an upper surface on which a plurality of gap pins GP having a predetermined height are arranged, and a thickness tg of the air gap AG may be defined by heights of the plurality of gap pins GP. For example, the thickness tg of the air gap AG may be in the range of 5 µm to 100 µm. In some embodiments, the thickness tg of the air gap AG may be in a range of 20 µm to 80 µm.

Referring to FIGS. 3 and 4, heat is transferred in the thickness direction (or vertical direction) with relatively high thermal conductivity in the section corresponding to the thickness ta of the first heating plate 151A, and the heat dispersion layer 158 between the first heating plate 151A and the second heating plate 151B may delay heat transfer in a vertical direction in a section corresponding to the thickness tg. By dispersing heat in the horizontal direction during this delay process, heat may be transferred again with high thermal conductivity while having a uniform temperature distribution over the entire area in a section corresponding to the thickness tb of the second heating plate 151B.

FIG. 3 illustrates a temperature distribution of the wafer W by the wafer heater 150. For example, referring to the temperature distribution of FIG. 3, a relatively high temperature is illustrated at the center of each heating resistance pattern 155, and this temperature deviation (ΔT) may be lowered to less than 0.1° C. (e.g., 0.05° C.) by the heat dispersion layer.

For the first heating plate 151A, a ceramic material having high thermal conductivity and excellent fire resistance and mechanical strength may be used. For example, the first heating plate 151A may be formed of a ceramic material such as AlN or Al₂O₃. In some embodiments, the second heating plate 151B may include the same material as the first heating plate 151A, but is not limited thereto. In some embodiments, the second heating plate 151B may use a material different from the material of the first heating plate 151A. For example, the thickness ta of the first heating plate 151A and the thickness tb of the second heating plate 151B may be 0.5 mm to 5 mm, respectively. In some embodiments, the thickness ta of the first heating plate 151A may be greater than the thickness tb of the second heating plate 151B.

To compensate for the heat transfer delay process by the heat dispersion layer 158 described in FIG. 4, the second heating plate 151B may include a material having a thermal conductivity that is higher than a thermal conductivity of the material of the first heating plate 151A. For example, the second heating plate 151B may include a metal such as silver (Ag) or copper (Cu), graphite, or graphene.

A plurality of support pins WP may be formed on the upper surface of the second heating plate 151B. The plurality of support pins WP separate the wafer W from the wafer heater 150 (e.g., the second heating plate 151B), such that the wafer W does not directly physically contact the upper surface of the second heating plate 151B. Through such non-contact, thermal energy generated by the first heating plate 151A and the second heating plate 151B may be more uniformly transferred to the entire surface of the wafer W rather than being concentrated in a specific area of the wafer W. The height of the plurality of support pins WP defines a gap between the wafer W and the second heating plate 151B. For example, the height of the plurality of support pins WP may be in a range of about 50 µm to about 300 µm.

A cooling plate 120 may be disposed on the base 112. After the baking process is completed, the heat of the first heating plate 151A and the second heating plate 151B may be discharged through the cooling plate 120. Heat of the first heating plate 151A and the second heating plate 151B may be transferred to the cooling plate 120 through a support 130 supporting an outer peripheral region 150P of the first heating plate 151A and the second heating plate 151B.

A wafer guide 175 is disposed on the outer peripheral region 150P of the second heating plate 151B, and the wafer guide 175 may guide the wafer W disposed on the plurality of support pins WP not to be separated from the wafer baking area. For example, since the wafer guide 175 may come into contact with the sidewall of the wafer W, unwanted movement of the wafer W passing through the wafer guide 175 may be suppressed. In some embodiments, a vacuum hole (not illustrated) may be implemented in the first heating plate 151A and the second heating plate 151B to more firmly support the wafer W on the second heating plate 151B. The vacuum hole is formed to pass through the first heating plate 151A and the second heating plate 151B and may be connected to an external vacuum pump. By depressurizing the space under the wafer W through the vacuum hole by the operation of the vacuum pump, the wafer W may be stably fixed to the wafer baking region.

Hereinafter, a process of forming a photoresist pattern will be described to demonstrate a baking process using a wafer baking apparatus.

First, a photoresist layer is coated on the wafer W to be disposed in the wafer baking apparatus 100. In some embodiments, the photoresist layer may be formed by spin coating using a mixture of a chemical component including a photosensitive material and a solvent. For example, chemical components may include substances such as a polymer, photoacid generator (PAG), quencher, chromophores, surfactant, and a crosslinking agent, and the solvent may include Propylene Glycol Monomethyl Ether (PGME), Propylene Glycol Monomethyl Ether Acetate (PGMEA), or a combination thereof.

Subsequently, the photoresist layer 160 may be exposed according to a predetermined pattern. For example, the exposure process may be performed using an illumination source such as KrF, ArF, or extreme ultraviolet (EUV) together with a photomask for selective exposure. As such, the wafer W having the exposed photoresist layer may be transferred to the wafer baking apparatus 100 illustrated in FIG. 1.

The photoresist layer of the wafer W disposed in the wafer baking apparatus 100 may be baked by the wafer heater 150. During the baking process, thermal uniformity may significantly affect device performance. Due to a non-uniform temperature distribution, the solvent remaining in the photoresist layer may be non-uniformly removed for each area, and therefore, a thickness deviation of the photoresist layer may occur, which may cause a device defect. As described above, in the wafer heater 150 according to the present embodiment, by introducing the heat dispersion layer 158 as a heat resistance element between the first heating plate 151A and the second heating plate 151B, the temperature distribution over the entire area may be significantly reduced, and as a result, the photoresist layer may be formed to have a constant thickness throughout the entire area.

In the process of baking the photoresist layer on the wafer W using the wafer heater 150, to smoothly discharge the evaporated solvent, a purge gas may be supplied to the inner space 100S through a supply unit 185. The purge gas supplied through the supply unit 185 may be sprayed onto the wafer W through a shower head 187. The shower head 187 may be disposed on the upper side of the inner space 110S of the chamber 110, for example, on the inner lower surface of the cover 114 to face the wafer heater 150. The purification gas may be uniformly diffused on the upper surface of the wafer W through injection holes of the shower head 187 (refer to the solid arrows). This allows the solvent to evaporate uniformly over the entire area of the photoresist layer formed on the wafer W, thereby stably correcting the uniformity of the thickness. In addition, a discharge unit 195 may be disposed on the upper portion of the wafer heater 150. In detail, the discharge unit 195 is formed on the upper side of the cover 114 to surround the upper region of the wafer heater 150 and may smoothly discharge the purification gas (refer to the dashed arrows).

After the above-described baking process is performed, the photoresist layer of the wafer W may be patterned through a developing process. This developing process may be performed by a nozzle configured to supply a developer solution to the photoresist layer of the wafer W. In this case, the developer solution may include a solvent developer such as 2-heptanone, n-butyl acetate (NBA), isoamyl acetate, or combinations thereof. For example, a positive-tone photoresist changes the chemical structure of the photoresist by exposure and the converted portion becomes more soluble in the developer solution. After the development process, the exposed portion of the photoresist layer is removed and the unexposed portion remains, thereby forming a photoresist pattern. Conversely, when the photoresist layer is a negative-tone photoresist, after the development process, the exposed portion remains and the unexposed portion is removed, thereby forming a photoresist pattern.

According to this embodiment, the first heating plate 151A and the second heating plate 151B is provided, and the air gap AG is between the first heating plate 151A and the second heating plate 151B as a thermal resistance element. Accordingly, a wafer baking apparatus 100 capable of heating the wafer W to a uniform temperature (e.g., less than 0.01° C.) may be provided, a photoresist pattern having excellent thickness uniformity may be provided, and the required performance of a manufactured device may be ensured.

The wafer baking apparatus 100 according to this embodiment is provided as an example and described as an apparatus for the baking process of the photoresist layer, but may also be implemented as a device for heat treatment to ensure a crystal of a film to be relatively dense after deposition of a thin film. In addition, the wafer baking apparatus 100 is not limited to a wafer baking apparatus, and may also be applied and implemented to other various heating devices for performing a process for semiconductor manufacturing when the wafer W is heated to a relatively high temperature.

Wafer heaters according to embodiments of the present disclosure may have a structure similar to the structure of the wafer heater illustrated in FIGS. 1 and 3, and an air gap as a heat dispersion layer is included, and the wafer temperature distribution is accordingly measured.

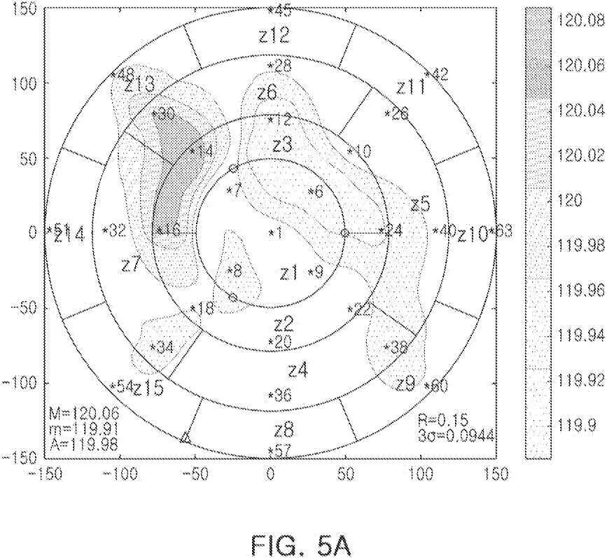

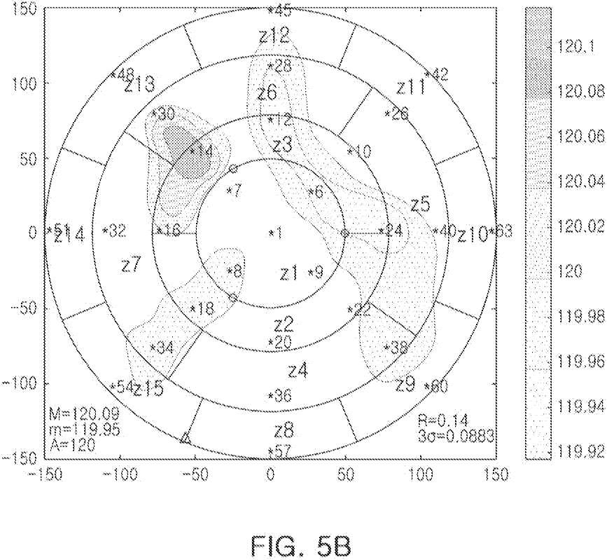

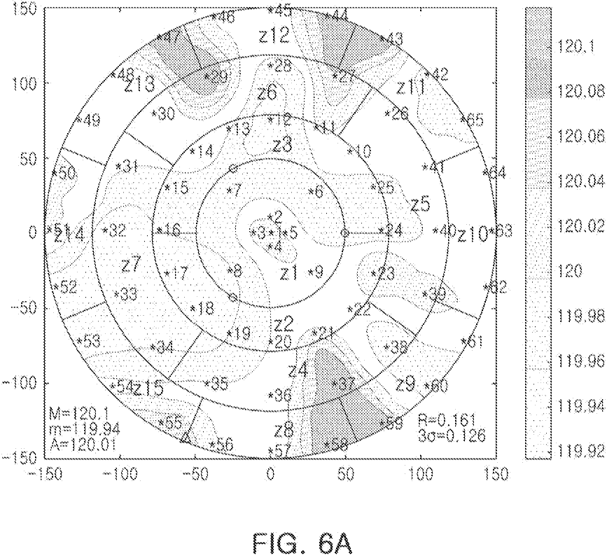

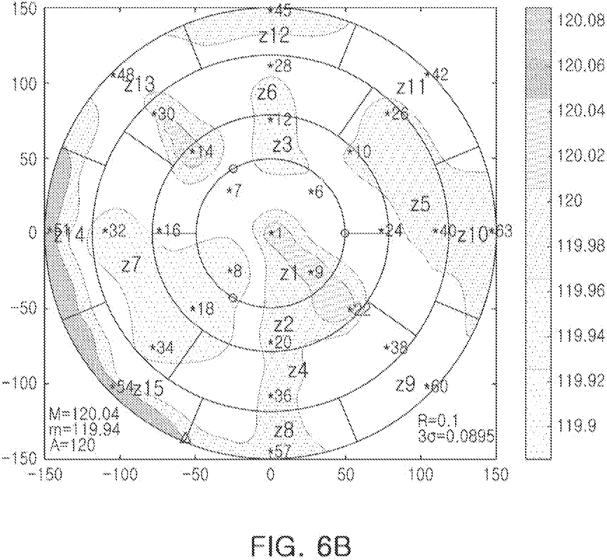

For example, FIGS. 5A and 6A illustrate the temperature distribution of a wafer heater that does not include a heat dispersion layer, and FIGS. 5B and 6B illustrate temperature distributions according to the introduction of air gaps of different thicknesses (10 µm and 30 µm), respectively.

First, referring to FIGS. 5A and 5B, the result of FIG. 5B illustrates a uniform temperature distribution over an entire area compared to FIG. 5A. In detail, the deviation (3σ) of the temperature distribution of FIG. 5A is 0.0944, whereas the deviation (3σ) of the temperature distribution of FIG. 5B is improved by about 12% (0.0883).

Referring to FIGS. 5A and 5B, the result of FIG. 5B illustrates a uniform temperature distribution over the entire area compared to FIG. 5A. In detail, the temperature distribution (R = M-m) was improved from 0.15 to 0.14, and the deviation (3σ) of the temperature distribution of FIG. 5A is 0.0944, whereas the deviation (3σ) of the temperature distribution of FIG. 5B was improved by about 12% (0.0883).

In addition, referring to FIGS. 6A and 6B, the temperature distribution (R = M-m) was significantly improved from 0.161 to 0.1, and the deviation (3σ) of the temperature distribution in FIG. 6A was 0.126, whereas the deviation (3σ) of the temperature distribution of FIG. 6B was significantly improved by about 40% (0.0895).

As such, the temperature distribution was improved uniformly by introducing an air gap, and it could be confirmed that the degree of the improvement was higher when the thickness of the air gap was 30 µm than when the thickness was 10 µm.

FIG. 7 is a cross-sectional view illustrating a wafer heater 150′ according to an example embodiment.

Referring to FIG. 7, the wafer heater 150′ according to the present embodiment may be understood as having a structure similar to that of the wafer heater 150 illustrated in FIGS. 1 to 3, except the wafer heater 150′ may include a heat-resistant adhesive layer as a heat dispersion layer 158′. In addition, the components of the present embodiment may be understood with reference to descriptions of the same or similar components of the wafer heater 150 illustrated in FIGS. 1 to 3 unless otherwise specified.

Similar to the previous embodiment, the wafer heater 150′ according to this embodiment includes the first and heating plate 151A and the second heating plate 151B, and the heat dispersion layer 158′ disposed therebetween. Unlike the previous embodiment, the heat dispersion layer 158′ may include a heat-resistant adhesive layer bonding the upper surface of the first heating plate 151A and the lower surface of the second heating plate 151B. The heat-resistant adhesive layer may be an adhesive resin layer having heat resistance, for example, an adhesive layer containing an epoxy resin. Since the heat-resistant adhesive layer has lower thermal conductivity than the thermal conductivity of the first heating plate 151A and the second heating plate 151B and has a relatively thin thickness, a heat dispersion effect similar to the air gap AG of FIG. 3 described above may be implemented.

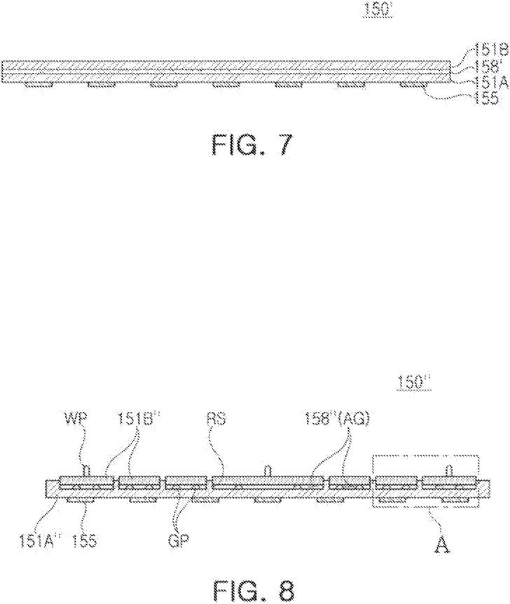

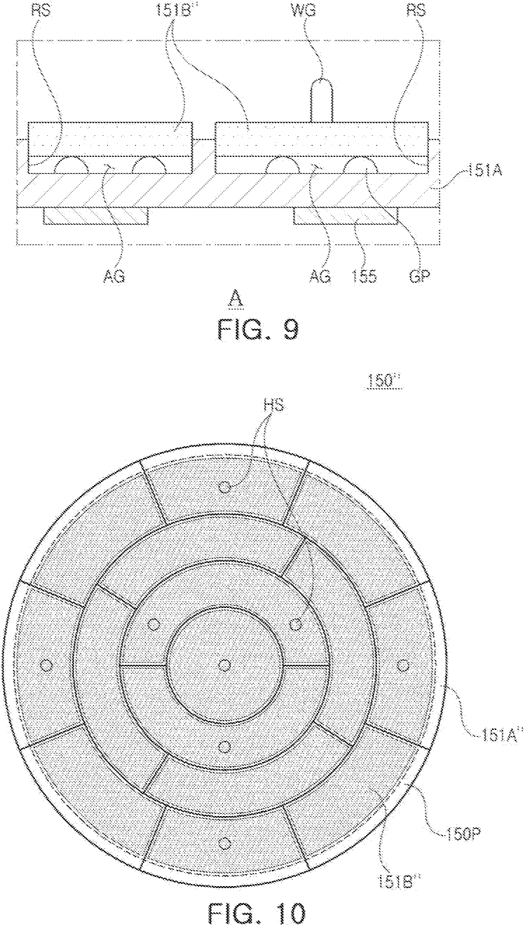

FIG. 8 is a cross-sectional view illustrating a wafer heater according to an example embodiment, FIG. 9 is a partially enlarged view illustrating part “A” of the wafer heater of FIG. 8, and FIG. 10 is a top plan view illustrating the wafer heater of FIG. 8.

Referring to FIGS. 8 to 10, a wafer heater 150″ according to the present embodiment may be understood as having a structure similar to the structure of the wafer heater 150 illustrated in FIGS. 1 to 3, except the wafer heater 150″ may include a first heating plate 151A″ having a plurality of receiving grooves RS, and a plurality of second heating plates 151B″ respectively disposed in the plurality of receiving grooves RS. In addition, the components of the present embodiment may be understood with reference to descriptions of the same or similar components of the wafer heater 150 illustrated in FIGS. 1 to 3 unless otherwise specified.

The wafer heater 150″ according to the present embodiment includes the first heating plate 151A″ having an upper surface formed with a plurality of receiving grooves RS, and a plurality of the second heating plates 151B″ respectively disposed in the plurality of receiving grooves RS. The plurality of receiving grooves RS may have a same depth as each other. Each of the second heating plates 151B″ may have a thickness equal to or greater than the depth of the plurality of receiving grooves RS.

As illustrated in FIG. 10, the wafer heater 150″ employed in this embodiment may be divided into 15 heating sectors HS in a plan view, similar to the example embodiment illustrated in FIGS. 2 and 3. The heating resistance pattern 155 may be disposed in each of the plurality of heating sectors HS to independently control the temperature of each of the plurality of heating sectors HS. The plurality of receiving grooves RS introduced in the present embodiment may be formed to have an area corresponding to the heating sectors HS, respectively, in the upper surface regions overlapping the plurality of heating sectors HS, respectively. The second heating plates 151B″ may also be formed to have an area corresponding to the plurality of heating sectors HS. The plurality of heating sectors HS may be independently temperature-controlled by the second heating plates 151B″.

The first heating plate 151A″ may include a plurality of gap pins GP disposed on the bottom surfaces of the plurality of receiving grooves RS, respectively, and having a predetermined height. A plurality of an air gap AG as a heat dispersion layer 158″ may be formed between the second heating plates 151B″ and the bottom surfaces of the plurality of receiving grooves RS by the plurality of gap pins GP. The air gap AG may implement uniform heat dispersion in the horizontal direction, through a heat transfer delay in the vertical direction with relatively high thermal resistance (refer to FIGS. 5B and 6B).

In another embodiment, instead of the air gap AG, a heat-resistant adhesive layer (see FIG. 7) for bonding the bottom surfaces of the plurality of receiving grooves RS and the lower surfaces of the plurality of second heating plates 151B″ to each other may also be included.

The first heating plate 151A and the second heating plate 151B may be formed of a same material, but in this embodiment, the second heating plate 151B″ may have a thermal conductivity that is higher than a thermal conductivity of the first heating plate 151A″. Through this arrangement, a delay in heat transfer due to the air gap AG may be provided and, for example, a decrease in the temperature increase rate may be compensated. For example, the first heating plate 151A includes a ceramic material having relatively high thermal conductivity and high rigidity, and the second heating plate 151B″ may include metal, graphite, or graphene.

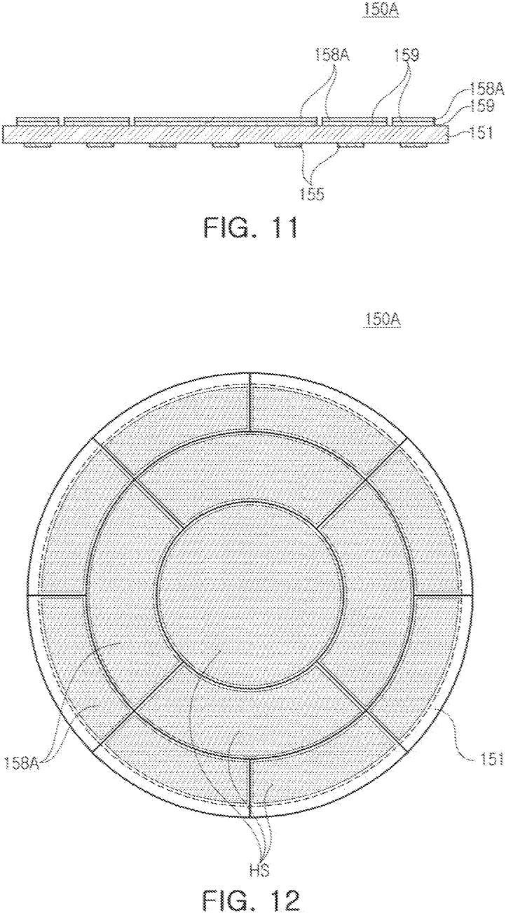

FIG. 11 is a cross-sectional view illustrating a wafer heater according to an example embodiment, and FIG. 12 is a top plan view illustrating the wafer heater of FIG. 11.

Referring to FIGS. 11 and 12, a wafer heater 150A according to an example embodiment includes a heating plate 151, a plurality of a heating resistance pattern 155 disposed on the lower surface of the heating plate 151, and a heat dispersion layer 158A disposed on the heating plate 151. The wafer heater 150A may be used as the wafer heater 150 of the wafer baking apparatus 100 illustrated in FIG. 1

Unlike the heat dispersion layer of the above-described embodiments, the heat dispersion layer 158A employed in this embodiment may be a heat conductive layer having horizontal thermal conductivity greater than vertical thermal conductivity, rather than a heat resistance element. For example, the heat dispersion layer 158A may include graphene or graphite having an orientation having horizontal thermal conductivity greater than vertical thermal conductivity. In some embodiments, the heat dispersion layer 158A may be graphene, and the graphene may have a high thermal conductivity (about 5000 W/m·K) with a two-dimensional planar structure. When the heating plate is AlN, the heat dispersion layer 158A that is graphene may have a thermal conductivity 20 times higher than a thermal conductivity (about 250 W/m·K) of the heating plate.

Graphite may also be considered as another material for the heat dispersion layer, which has a significantly lower vertical thermal conductivity than horizontal thermal conductivity, with a layer structure. For example, the horizontal thermal conductivity of graphite is very excellent, from about 1,500 W/m·K to about 1,700 W/m·k, whereas the vertical thermal conductivity of graphite is only about 15 W/m·k. Therefore, by lamination in a layered structure on the heating plate 151 using these characteristics, a uniform temperature distribution may be implemented by reinforcing the thermal conductivity in the horizontal direction.

As illustrated in FIG. 12, the wafer heater 150A may be divided into a plurality of heating sectors HS in a plan view, similar to the previous embodiment. Although the present embodiment is illustrated with 13 heating sectors HS as an example, the number of heating sectors is not limited thereto. A plurality of the heating resistance pattern 155 may be formed on the lower surface of the heating plate 151 to independently control the temperature in a region corresponding to each of the plurality of heating sectors HS. The heat dispersion layer 158A employed in this embodiment may include a plurality of patterns disposed to be separated from each other in the upper surface regions corresponding to the plurality of heating sectors of the heating plate respectively.

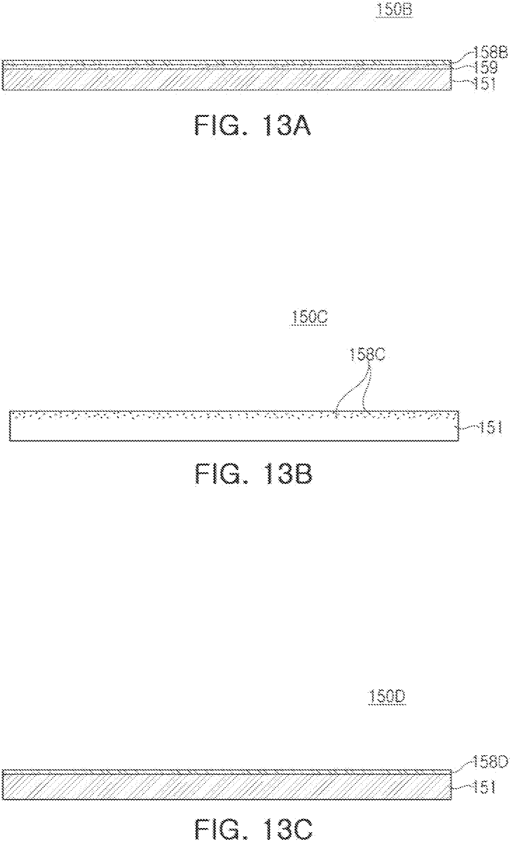

As illustrated in FIG. 11, the heat dispersion layer 158A may be pre-fabricated as a sheet having an adhesive layer 159 formed on the lower surface thereof and may be attached to the upper surface of the heating plate 151 using the adhesive layer 159, but the formation method is not limited thereto. For example, the heat dispersion layer 158A may be implemented in various forms (refer to FIGS. 13A to 13C).

FIGS. 13A to 13B are cross-sectional views illustrating a wafer heater according to various embodiments. First, referring to FIG. 13A, a wafer heater 150B according to an example embodiment may be understood as having a structure similar to the structure of the wafer heater 150A illustrated in FIGS. 11 and 12, except that a single heat dispersion layer 158B is employed. In addition, the components of the present embodiment may be understood with reference to descriptions of the same or similar components of the wafer heater 150A illustrated in FIGS. 11 and 12 unless otherwise specified.

A heat dispersion layer 158B employed in this embodiment is not divided according to a plurality of heating sectors (HS in FIG. 12), and may be attached to the upper surface of the heating plate 151 in the form of a single sheet by an adhesive layer 159. The heat dispersion layer 158B may include graphene or graphite having an orientation having horizontal thermal conductivity greater than vertical thermal conductivity.

Referring to FIG. 13B, a wafer heater 150C according to the present embodiment may be understood as having a structure similar to the structure of the wafer heater 150A illustrated in FIGS. 11 and 12, except that a thermally conductive powder 158C having relatively high thermal conductivity is employed in the upper region of the heating plate 151. In addition, the components of the present embodiment may be understood with reference to descriptions of the same or similar components of the wafer heater 150A illustrated in FIGS. 11 and 12 unless otherwise specified.

The heating plate 151 according to the present embodiment includes a thermally conductive powder 158C having a thermal conductivity higher than the thermal conductivity of the heating plate 151. The thermally conductive powder 158C may include graphite powder or graphene powder. The thermally conductive powder 158C may be disposed on or in the upper region of the heating plate 151. In the lower region of the heating plate 151, thermal stress due to the heating resistance pattern acts greatly and thus high rigidity may be required, and the thermally conductive powder 158C may be distributed around the upper region of the heating plate 151 to avoid a decrease in strength due to thermally conductive powder 158C in the lower region.

Referring to FIG. 13C, a wafer heater 150D according to the present embodiment may be understood as having a structure similar to that of the wafer heater 150A illustrated in FIGS. 11 and 12, except for depositing a heat dispersion layer 158D on the upper surface of the heating plate 151. In addition, the components of the present embodiment may be understood with reference to descriptions of the same or similar components of the wafer heater 150A illustrated in FIGS. 11 and 12 unless otherwise specified.

Unlike the example embodiment illustrated in FIG. 13A, the heat dispersion layer 158D employed in this embodiment is not attached by an adhesive layer, and may be formed on the upper surface of the heating plate 151 by a direct deposition process. For example, the heat dispersion layer 158D may include a graphene layer or a graphite layer deposited using a process such as chemical vapor deposition (CVD). The deposition process of the heat dispersion layer 158D may be performed to have an orientation having horizontal thermal conductivity greater than vertical thermal conductivity. When the heat dispersion layer 158D is provided by direct deposition, as no heat-resisting material is used, as in an adhesive layer, the effect of the heat dispersion layer 158D may be improved.

As set forth above, according to example embodiments, a wafer baking apparatus capable of heating a wafer to a uniform temperature (e.g., less than 0.01° C.) by dividing a heating plate into lower and upper structures (e.g., first and second heating plates) and including a heat-resisting structure such as an air gap therebetween, as a heat dispersion layer, may be provided. In some embodiments, a similar effect may be provided by applying a material having horizontal thermal conductivity higher than vertical thermal conductivity to a heating plate in a heat dispersion structure.

While example embodiments have been illustrated and described above, it will be apparent to those skilled in the art that modifications and variations may be made without departing from the scope of the present disclosure.

What is claimed is:

1. A wafer baking apparatus comprising:
a chamber comprising a processing space; and
a wafer heater disposed in the processing space and configured to support a wafer;
wherein the wafer heater comprises:
a first heating plate;
a heating resistance pattern disposed on a lower surface of the first heating plate;
a second heating plate disposed on the first heating plate; and
a heat dispersion layer interposed between the first heating plate and the second heating plate, and having a thermal conductivity that is lower than a thermal conductivity of materials of the first heating plate and the second heating plate.

2. The wafer baking apparatus of claim 1, wherein the heat dispersion layer comprises an air gap.

3. The wafer baking apparatus of claim 2, wherein the first heating plate has an upper surface on which a plurality of gap pins are arranged, and the air gap is defined by heights of the plurality of gap pins.

4. The wafer baking apparatus of claim 2, wherein the air gap has a thickness in a range of 5 µm to 100 µm.

5. The wafer baking apparatus of claim 1, wherein the heat dispersion layer comprises a heat-resistant adhesive layer that bonds an upper surface of the first heating plate to a lower surface of the second heating plate.

6. The wafer baking apparatus of claim 1, wherein the wafer heater defines a plurality of heating sectors in a plan view, and
wherein the heating resistance pattern comprises a plurality of heating resistance patterns which are disposed in the plurality of heating sectors, respectively, and are configured to be controlled to heat independently from each other.

7. The wafer baking apparatus of claim 6, wherein the first heating plate comprises a plurality of receiving grooves that are disposed in an upper surface area of the first heating plate and correspond to the plurality of heating sectors, respectively, and
wherein the second heating plate comprises a plurality of second heating plates respectively disposed in the plurality of receiving grooves.

8. The wafer baking apparatus of claim 7, wherein the first heating plate further comprises a plurality of gap pins disposed on bottom surfaces of the plurality of receiving grooves, respectively.

9. The wafer baking apparatus of claim 7, wherein the wafer baking apparatus further comprises a heat-resistant adhesive layer that bonds bottom surfaces of the plurality of receiving grooves and lower surfaces of the plurality of second heating plates to each other.

10. The wafer baking apparatus of claim 1, wherein the first heating plate and the second heating plate comprise a same ceramic material.

11. The wafer baking apparatus of claim 1, wherein the second heating plate has a thermal conductivity that is higher than a thermal conductivity of the first heating plate.

12. The wafer baking apparatus of claim 11, wherein the first heating plate comprises a ceramic material, and
the second heating plate comprises a metal.

13. The wafer baking apparatus of claim 11, wherein the first heating plate comprises a ceramic material, and
the second heating plate comprises graphite or graphene.

14. A wafer baking apparatus comprising:
a chamber comprising a processing space; and
a wafer heater disposed in the processing space, configured to support a wafer, and defining a plurality of heating sectors in a plan view,
wherein the wafer heater comprises:
a first heating plate comprising a plurality of receiving grooves respectively disposed in upper surface regions of the first heating plate that correspond to the plurality of heating sectors;
a plurality of heating resistance patterns disposed in the plurality of heating sectors, respectively, and configured to be controlled to heat independently from each other;
a plurality of second heating plates disposed in the plurality of receiving grooves, respectively; and
a plurality of heat dispersion layers that each have a thermal conductivity that is lower than a thermal conductivity of materials of the first heating plate and the plurality of second heating plates, the plurality of heat dispersion layers being between bottom surfaces of the plurality of receiving grooves and a top surface of the plurality of second heating plates.

15. The wafer baking apparatus of claim 14, wherein the plurality of heat dispersion layers comprises an air gap, and
the first heating plate comprises a plurality of gap pins respectively disposed on the bottom surfaces of the plurality of receiving grooves and defining a thickness of the air gap.

16. The wafer baking apparatus of claim 14, wherein the plurality of second heating plates each comprise a material having a thermal conductivity that is higher than a thermal conductivity of a material of the first heating plate.

17. A wafer baking apparatus comprising:
a chamber comprising a processing space; and
a wafer heater disposed in the processing space and configured to support a wafer,
wherein the wafer heater comprises:
a heating plate;
a heating resistance pattern disposed on a lower surface of the heating plate; and
a heat dispersion layer disposed on the heating plate and having a horizontal thermal conductivity that is greater than a vertical thermal conductivity of the heat dispersion layer.

18. The wafer baking apparatus of claim 17, wherein the wafer heater defines a plurality of heating sectors in a plan view, and
the heat dispersion layer comprises a plurality of heat dispersion patterns separated from each other in respective upper surface regions of the wafer heater that correspond to the plurality of heating sectors of the heating plate.

19. The wafer baking apparatus of claim 17, wherein the heat dispersion layer comprises graphene having an orientation in which a horizontal thermal conductivity of the graphene is greater than a vertical thermal conductivity of the graphene.

20. The wafer baking apparatus of claim 19, further comprising an adhesive layer disposed between the heat dispersion layer and the heating plate.
